(19) United States
(12) Patent Application Publication
(10) Pub. No.: US 2022/0037583 A1
(43) Pub. Date: Feb. 3, 2022

(54) PIEZOELECTRIC MATERIAL AND PIEZOELECTRIC DEVICE

(71) Applicant: RF360 EUROPE GMBH, Munchen (DE)

(72) Inventors: Ivoyl KOUTSAROFF, Munchen (DE); Christopher Hayden HONTGAS, Orlando, FL (US)

(21) Appl. No.: 17/297,898

(22) PCT Filed: Dec. 18, 2019
(86) PCT No.: PCT/EP2019/085999

§ 371 Date: May 27, 2021

(30) Foreign Application Priority Data
Dec. 21, 2018 (DE) 10 2018 133 377.3

(51) Int. Cl. H01L 41/187; H03H 9/02; C04B 35/581

(52) U.S. Cl. CPC H01L 41/187; C04B 35/581; H03H 9/02031

(57) ABSTRACT

Piezoelectric nitride compound materials with improved properties are provided. The piezoelectric material comprises aluminum, nitrogen and binary and ternary dopants that can be selected from silver, niobium and/or scandium or from silver and/or niobium.

The present invention refers to a piezoelectric material and to piezoelectric devices comprising the piezoelectric material.

Piezoelectric materials can be utilized to due to their piezoelectric effect convert mechanical energy to electrical energy and convert electrical energy into mechanical energy. Piezoelectric materials can be used in a wide variety of devices. For example electro acoustic RF devices comprising electro acoustic resonators can have resonating structures where electrode structures and a piezoelectric material are combined. The performance of piezoelectric materials is determined by sets of elastic, dielectric, and piezoelectric parameters. Elastic parameters are, for example, Young's modulus, C₃₃ (a component of the material's stiffness tensor), lattice density and the like. The electromechanical coupling coefficient, κ², which is another important parameter determining the efficiency of acoustic wave excitation bridges the mechanical and electrical performance, Another parameter is the piezoelectric constant, e₃₃, a component of the material's piezoelectric tensor. Others are the longitudinal stiffness, c33, and the dielectric permittivity, ε₃₃.

For example, for electro acoustic applications it is preferred that the piezoelectric material have a high electromechanical coupling coefficient, κ². A known piezoelectric material is the wurtzite-type AlN (aluminium nitride) that can be used in electro acoustic resonators, e.g. in BAW resonators (BAW=bulk acoustic wave). BAW resonators have a bottom electrode, a top electrode above the bottom electrode and the piezoelectric material sandwiched between the bottom electrode and the top electrode. It is preferred that the piezoelectric material of BAW resonators can be provided via a thin film deposition technique.

A further known piezoelectric material is Sc doped AlN (scandium doped AlN). Sc doped AlN has the potential to provide a higher electromechanical coupling coefficient κ², than pure aluminium nitride.

However, the desire for alternative materials suitable for use in piezoelectric devices exists. Further, it was found that Sc doping can deteriorate a corresponding device's mechanical properties due to AlScN lattice softening, manifested in the reduction of the longitudinal stiffness coefficient, C₃₃.

What is wanted is a piezoelectric material that can be used in a wide variety of piezoelectric devices, that has improved piezoelectric properties, in particular an increased electromechanical coupling coefficient, κ², and that has good mechanical properties, in particular a high longitudinal stiffness coefficient, C₃₃, simultaneously, i.e., without having these performance parameters to have a trade-off effect.

To that end, a piezoelectric material according to the independent claim and a piezoelectric device are provided. Dependent claims provide preferred embodiments.

In the following compositions for piezoelectric materials are provided. The tolerance level for the quantities of the atoms where the compositions can be regarded as equivalent can be ±1 atomic % or ±2 atomic %.

The piezoelectric material comprises as its main constituent Al₁₋ₓ[(Agₐ, Nb_{b}, Sc_{c})_{y}]ₓN. a is larger than or equal to 0.055 and smaller than or equal to 1.33. b is larger than or equal to 0.055 and smaller than or equal to 1.33.

c is larger than or equal to 0. x is larger than or equal to 0.03 and smaller than or equal to 0.75.

It is also possible that 0.001≤a≤0.124 and 0.001≤b≤0.124.

Thus, the piezoelectric material comprises Al (aluminium), Ag (silver), Nb (niobium) and N (nitrogen).

Further, the material can comprise Sc (Scandium).

Ag and Nb—and if present Sc—establish dopants that can replace Al. The value of y is chosen such that the dopants can be regarded as a group where each atom of the dopants group that can fractionally substitute for Al in the wurtzite lattice of Al₁₋ₓ[(Agₐ, Nb_{b}, Sc_{c})_{y}]ₓN. Then, x denotes the doping/replacement level of Al atoms.

It was found that such a piezoelectric material has good piezoelectric properties such as a good electromechanical coupling coefficient, κ². Further, the piezoelectric material with the main constituent as described above also can have a higher stiffness, in particular a higher stiffness parameter C₃₃ compared to pure AlN or Sc doped AlN, of a comparable electromechanical coupling coefficients κ².

Further, it was found that the piezoelectric material as described above allows piezoelectric resonators with an increased quality factor, Q, compared to electro acoustic resonators based on pure AlN or Sc doped AlN. Thus, corresponding RF filters or other piezoelectric components with an improved performance are possible.

It is possible that 0.03≤x≤0.372.

It is possible that the doping level x is selected from 0.03, 0.06, 0.0625, 0.09, 0.12, 0.15, 0.18, 0.21, 0.24, 0.27, 0.30, 0.33, 0.36, 0.39, 0.42, 0.45, 0.48, 0.51, 0.54, 0.57, 0.60, 0.63, 0.66, 0.69, 0.72 and 0.75.

It is possible that the main constituent is Al_{0.875}Ag_{0.0625}Nb_{0.0625}N. Then, the dopants are Ag and Nb.

It is possible that the main constituent is the main constituent is Al_{0.814}Ag_{0.062}Nb_{0.062}Sc_{0.062}N. Then, the dopants are Ag, Nb and Sc.

It is possible that at least 25.6 (atomic %), 31.8 (atomic %), 38.0% (atomic %), 44.2 (atomic %), 50.4 (atomic %), 56.6 (atomic %), 62.8 (atomic %), 690.0 (atomic %), 75.2 (atomic %), 81.4 (atomic %), 87.6 (atomic %), 90.8 (atomic %), 930.8 (atomic %), 95.8 (atomic %), 98.0 (atomic %) are Al while the remaining balance is a combination of binary doped AlN piezoelectric material containing Ag (silver) and Nb (niobium).

It is possible that at least 25.6 (atomic %), 30.25 (atomic %), 34.9% (atomic %), 44.2 (atomic %), 53.5 (atomic %), 62.8 (atomic %), 72.1 (atomic %), 75.4 (atomic %), 81.4 (atomic %), 87.4 (atomic %), 90.7 (atomic %), 93.8 (atomic %), 95.35 (atomic %), 96.28 (atomic %), 96.9 (atomic %) are Al while the remaining balance is a combination of binary doped AlN piezoelectric material containing Ag (silver), Nb (niobium) and Sc (scandium).

The above compositions of quaternary or quinary nitrides provide good electro mechanical properties and good mechanical properties which are shown in the following tables (Table 1 and Table 2). The Ab initio properties are derived from density functional perturbation theory calculations. Comparisons between calculations and experiments justify that the provided calculated values can be regarded close to the expected experimental values as sufficient number of quasi-random structures (SQS) and median statistical values had been obtained for each composition example.

TABLE 1

| | | Voigt | | |
|---|---|---|---|---|
| | | Young's | | Lattice |
| Nitride Compound | C₃₃ | modulus E | e₃₃ | density |
| Composition | [GPa] | [GPa] | [C/m²] | [g/cm³] |
| reference: AlN | 356.8 | 299.55 | 1.4638 | 3.203 |
| reference: Al0.875Sc0.125N | 286.1 | 249.93 | 1.6655 | 3.237 |
| A) | 293.1 | 224.25 | 1.9733 | 3.745 |
| Al0.875Ag0.0625Nb0.0625N | | | | |
| B) | 267.7 | 226.03 | 2.155 | 3.772 |
| Al0.814Ag0.062Nb0.062Sc0.062N | | | | |
| reference: Al0.8125Sc0.1875N | 260.7 | 228.57 | 1.8383 | 3.258 |

TABLE 2

| | | | | Stiffened |
|---|---|---|---|---|
| | k² = e₃₃²/ | Dielectric | Piezoelectric | Longitudinal |
| Nitride Compound | (C₃₃∈₃₃∈ₒ) | permittivity | coefficient | Velocity |
| Composition | [%] | ∈₃₃ | d₃₃(pC/N) | [m/s] |
| reference: AlN | 7.02 | 9.763 | 5.31 | 10864 |
| reference: Al0.875Sc0.125N | 10.204 | 10.733 | 8.6679 | 9868.9 |
| A) | 10.99 | 13.656 | 10.57 | 9319.9 |
| Al0.875Ag0.0625Nb0.0625N | | | | |
| B) | 12.35 | 15.87 | 11.685 | 8929.4 |
| Al0.814Ag0.062Nb0.062Sc0.062N | | | | |
| reference: Al0.8125Sc0.1875N | 12.89 | 11.36 | 11.516 | 9504.4 |

Residual constituents can comprise other atoms that may be unavoidable due to necessary manufacturing steps and the like.

It is possible that a piezoelectric device comprises a material as described above.

Such a device can be selected from
an electro acoustic resonator, a SAW resonator, a SAW filter, a solidly mounted reflector, SMR, BAW resonator, a (SMR-)BAW filter, a guided BAW(GBAW) resonator, a GBAW filter, a film bulk acoustic wave (FBAR) resonator, a FBAR filter,
a device working with Lamb waves, acoustic plate wave (APW), Rayleigh SAW (R-SAW), Sezawa mode waves, shear-horizontal SAWs (SH-SAWs), Love mode waves, pseudo-surface acoustic waves (PSAW) or Leaky SAWs (LSAW),
a multiplexer, a duplexer, a quadplexer, a hexaplexer, a multiplexer based on any of the above types of resonators, a piezoelectric generator, a piezoelectric sensor, a mass sensor, a microfluidic sensor, a piezoelectric transducers, an energy harvester, an ultrasound device, a transducer or transmitter, a piezo (MEMS) microphone or a similar device that utilizes direct or reverse piezoelectric effect in a thin film or bulk ceramic form.

A SAW filter is an RF filter that has at least one SAW resonator. A SAW resonator has a piezoelectric material and interdigitated electrode structures comprising electrode fingers arranged one next to another on the piezoelectric material. Each electrode finger is electrically connected to one of two bus bars. When an RF signal is applied to the bus bars then due to the piezoelectric effect the electrode structure converts between RF signals and acoustic waves. The wavelength of the acoustic wave is essentially determined by the distance between adjacent electrode fingers of the same polarity. A surface wave propagating at the surface of the piezoelectric material is established. The frequency depends on the wavelength and on the wave velocity. Utilizing such resonators, e.g. as series resonators and as parallel resonators in a ladder-type structure or as resonators in a lattice-type structure allows to create a bandpass filter or a band rejection filter, e.g. for wireless communication devices.

In a BAW resonator the piezoelectric material is sandwiched between a bottom electrode and a top electrode. While the acoustic waves in a SAW resonator propagate in a direction parallel to the surface of the piezoelectric material, in a BAW resonator the acoustic wave propagates in a vertical direction. To confine acoustic energy to the resonator structure the resonator structure must be acoustically decoupled from its environment.

Correspondingly, it is possible that the BAW resonator is a SMR-type resonator (SMR=solidly mounted resonator) or a FBAR-type resonator (FBAR=film bulk acoustic wave resonator). In a SMR-type resonator the resonator structure is arranged on an acoustic mirror comprised of two or more layers of high and low acoustic impedance to act as an acoustic Bragg mirror to confine the acoustic energy. In a FBAR-type resonator the bottom electrode can be arranged above a cavity to acoustically isolate the resonator structure.

In a GBAW filter electrode structures are similar to that of a resonator in a SAW filter. However, the acoustic waves propagate in a longitudinal direction at an interface between the piezoelectric material and a cover layer such that a waveguiding structure is obtained.

Bandpass filters can be combined—possibly with additional impedance-matching circuits—to establish a multiplexer. For example in a duplexer a transmission filter and a reception filter are combined such that to-be-sent RF signals and to-be-received RF signals can share a common antenna port but propagate in separated signal paths, in a transmission signal path and in a reception signal path, respectively. Correspondingly, a multiplexer of a higher degree, e.g. a quadplexer comprises additional bandpass filters and additional signal paths.

In an energy harvester the piezoelectric material can be utilized to convert mechanical energy into electric energy, e.g. to load a battery or a capacitor with mechanical energy obtained from the environment of the respective device.

Thus, an improved piezoelectric material that allows improved piezoelectric devices, especially resonator devices with an improved quality factor, is provided.

The piezoelectric devices are not limited to the devices stated above. Further devices are also possible.

In the figures:

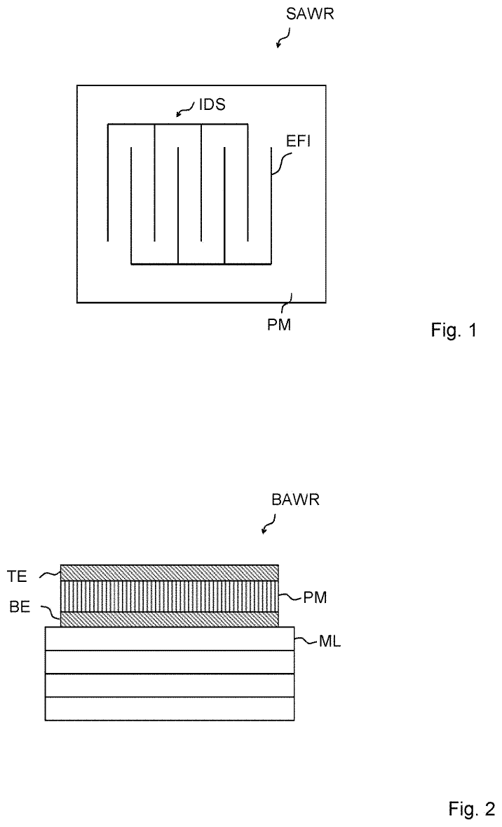

FIG. 1 illustrates the arrangement of an interdigital structure of a SAW resonator;

FIG. 2 illustrates the arrangement of a SMR-BAW resonator;

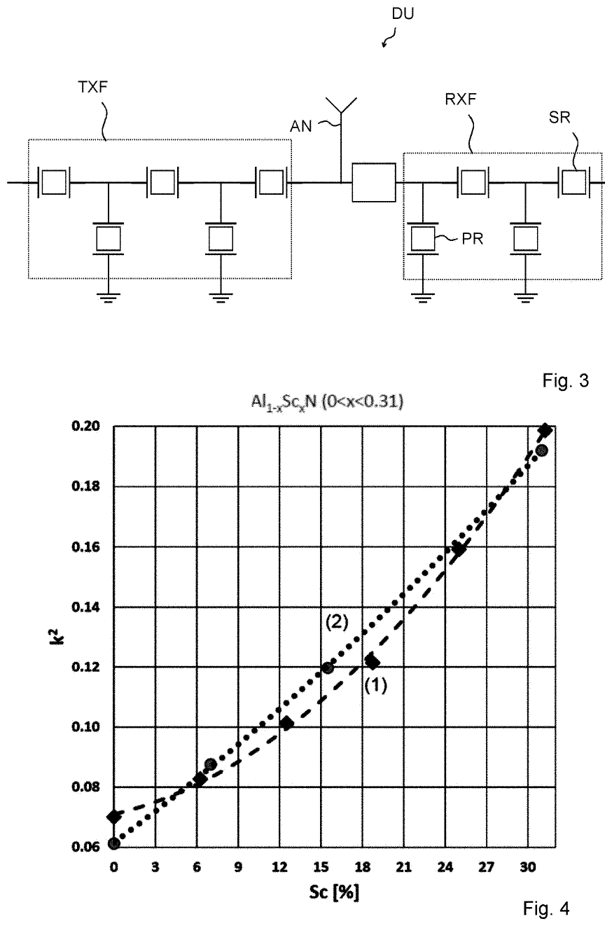

FIG. 3 illustrates the combination of electro acoustic resonators to establish a duplexer;

FIG. 4 shows comparisons between calculated values of electromechanical coupling coefficient, κ² and measured values from actual SMR-BAW resonators with piezoelectric layers made from different doping levels of Sc in AlN;

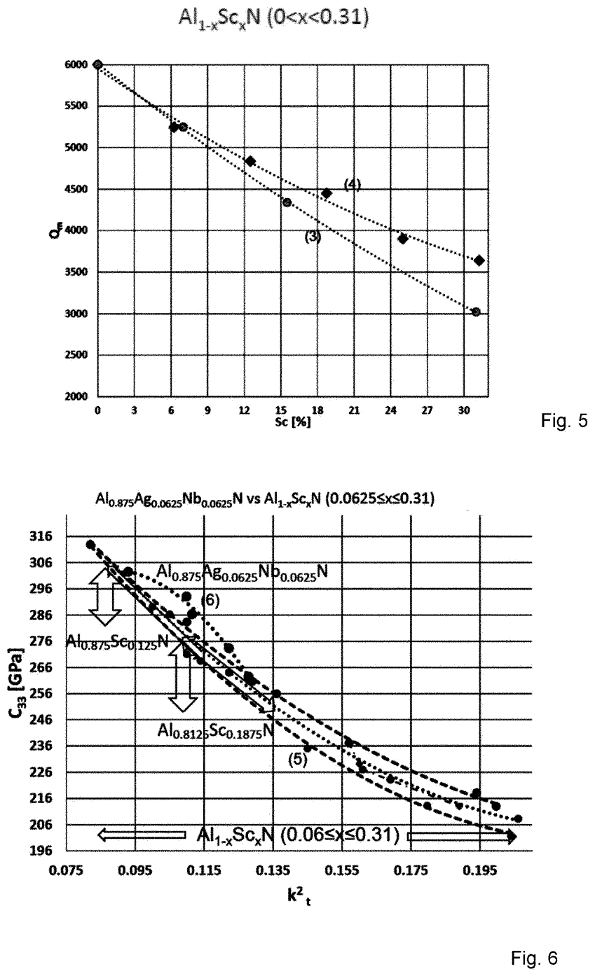

FIG. 5 shows a comparison between extrapolated mechanical Quality Factor (Qₘ) for measured from SMR-BAW and obtained values from ab-initio calculations and it is showing how quickly Qₘ is changing with different doping levels of Sc in AlN;

FIG. 6 shows the dependence of C₃₃ vs coupling coefficient κ² behaviour for an alternative to Al₁₋ₓScₓN (0.0625≤x≤0.31) material with a higher C₃₃ for a range of coupling coefficients κ²;

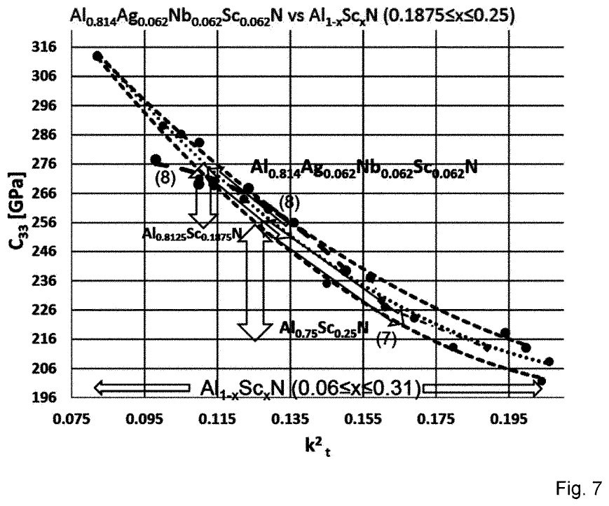

FIG. 7 shows the dependence of C₃₃ vs coupling coefficient κ² behaviour for an alternative to Al₁₋ₓScₓN (0.0625≤x≤0.31) material with a moderately higher C₃₃ for a range of coupling coefficients κ².

FIG. 1 illustrates a basic arrangement of electrode structures on a piezoelectric material PM that can be provided as a single crystal piezoelectric substrate or by piezoelectric material provided as a thin layer. The electrode structure has an interdigitated structure, IDS, comprising electrode fingers, EFI, arranged one next to another. Each of the electrode fingers, EFI, is electrically connected to one of two bus bars. In the arrangement shown in FIG. 1, the acoustic waves propagate at the surface of the piezoelectric material in a direction orthogonal to the electrode fingers.

FIG. 2 illustrates the basic construction of a BAW resonator BAWR. The BAW resonator BAWR has the piezoelectric material, PM, sandwiched between a bottom electrode, BE, and a top electrode, TE. FIG. 2 also illustrates an SMR-type resonator where the resonator structure comprising the two electrodes and the piezoelectric material is arranged on an acoustic mirror. The acoustic mirror has mirror layers, ML. Adjacent mirror layers, ML, have different acoustic impedance. At an interface between different mirror layers, ML, of different acoustic impedance, a part of the acoustic energy is reflected such that the combination of mirror layers, ML, establishes a Bragg mirror to confine the acoustic energy.

FIG. 3 illustrates the possibility of combining a transmission filter, TXF, and a reception filter, RXF, to establish a duplexer. The transmission filter, TXF, and the reception filter, RXF, comprise a signal path in which series resonators, SR, are electrically connected in series. Parallel resonators, PR, are electrically connected in shunt paths between the signal path and ground. An impedance matching circuit can be arranged between the transmission filter, TXF, and the reception filter, RXF, to provide matched frequency dependent impedances at the common port at which an antenna, AN, can be connected.

FIG. 4 shows a comparison between measured and calculated data. Curve (1) shows the experimentally measured dependence of the coupling factor, κ², on the Sc doping level of Sc doped AlN (Al₁₋ₓScₓN) for different doping levels, x. Curve (2) shows the results of calculations made in a simulation for determining a theoretical model of Sc doped AlN. It can be seen that the experiments essentially verify the ab-initio calculated results.

Similarly, FIG. 5 shows a comparison between measured and calculated data. Curve (3) shows the measured dependence of the mechanical quality factors, Qm, derived from the impedance response of experimentally fabricated resonators on the Sc doping level of Sc doped AlN (Al₁₋ₓScₓN). Curve (4) shows the results of calculations made in the simulation. Again, the experimentally derived values essentially verify the calculated results.

Thus, the calculations on which the present compositions base are reliable.

FIG. 6 shows a comparison between a plurality of parameters of Sc doped AlN and Al_{0.875}Ag_{0.0625}Nb_{0.0625}N (corresponding to composition A) of the tables). The Sc doping level for the different Sc doped AlN composition essentially determines C₃₃ as shown by curves (5). Curve (6) shows a polynomial interpolation of calculated data points indicating a C₃₃ dependence on κ2 for different quasi-random structures of Al_{0.875}Ag_{0.0625}Nb_{0.0625}N. The different quasi-random structures of Al_{0.875}Ag_{0.0625}Nb_{0.0625}N differ in an exact position of each dopant that substitutes the Al atoms. The calculations show that in a real composition a mixture of these quasi-random structures is provided such that a κ² of approximately 0.11 and a C₃₃ of 293.1 GPa are obtained. Thus, Al_{0.875}Ag_{0.0625}Nb_{0.0625}N has a C₃₃ that is approximately 7.0 GPa larger than that of Sc doped AlN baseline system with very similar κ² (close to 0.10), while the median value of Al_{0.875}Ag_{0.0625}Nb_{0.0625}N has C₃₃ that is approximately 1.25 GPa smaller (within the margin of error) than that of Sc doped AlN baseline system with the very similar κ² (close to 0.101).

FIG. 7 shows a comparison between a plurality of parameters of Sc doped AlN and Al_{0.814}Ag_{0.062}Nb_{0.062}Sc_{0.062}N (corresponding to composition B) of the tables). The Sc doping level for the different Sc doped AlN composition essentially determines C₃₃ as shown by curves (7). Curve (8) shows a polynomial interpolation of calculated data points indicating a C₃₃ dependence on κ² for different quasi-random structures of Al_{0.814}Ag_{0.062}Nb_{0.062}Sc_{0.062}N. The different quasi-random structures of Al_{0.814}Ag_{0.062}Nb_{0.062}Sc_{0.062}N differ in an exact position of each dopant that substitutes the Al atoms. The calculations show that in a real composition a mixture of these quasi-random structures is provided such that a κ² of approximately 0.115 and a C₃₃ of 268.4 GPa are obtained. Thus, Al_{0.876}Ca_{0.062}Ru_{0.062}B_{0.124}N has a C₃₃ that is approximately 3.8 GPa with very similar κ² (close to 0.12).

### LIST OF REFERENCE SIGNS

AN: antenna
BAWR: BAW resonator
BE: bottom electrode
DU: duplexer
EFI: electrode finger
IDS: interdigitated electrode structure
ML: acoustic mirror layer
PM: piezoelectric material
PR: parallel resonator
RXF: reception filter
SAWR: SAW resonator
SR: series resonator
TE: top electrode
TXF: transmission filter

1. A piezoelectric material, comprising:
Al₁₋ₓ[(Agₐ, Nb_{b}, Sc_{c})_{y}]ₓN as its main constituent,
wherein:
0.055≤a≤1.33 or 0.001≤a≤0.124;
0.055≤b≤1.33 or 0.001≤b≤0.124;
0≤c;
y=1/(a+b+c); and
0.03≤x≤0.75.

2. The piezoelectric material of claim 1, wherein:
0.001≤a≤0.124;
0.001≤b≤0.124; and
0.03≤x≤0.372.

3. The piezoelectric material of claim 1, wherein x is selected from 0.03, 0.06, 0.0625, 0.09, 0.12, 0.15, 0.18, 0.21, 0.24, 0.27, 0.30, 0.33, 0.36, 0.39, 0.42, 0.45, 0.48, 0.51, 0.54, 0.57, 0.60, 0.63, 0.66, 0.69, 0.72 and 0.75.

4. The piezoelectric material of claim 1, wherein the main constituent is Al_{0.875}Ag_{0.0625}Nb_{0.0625}N.

5. The piezoelectric material of claim 1, wherein the main constituent is Al_{0.814}Ag_{0.062}Nb_{0.062}Sc_{0.062}N.

6. The piezoelectric material of claim 1, wherein in the main constituent at least 25.6 (atomic %), 31.8 (atomic %), 38.0% (atomic %), 44.2 (atomic %), 50.4 (atomic %), 56.6 (atomic %), 62.8 (atomic %), 69.0 (atomic %), 75.2 (atomic %), 81.4 (atomic %), 87.6 (atomic %), 90.8 (atomic %), 93.8 (atomic %), 95.8 (atomic %), 98.0 (atomic %) are Al while the remaining balance is a combination of binary doped AlN piezoelectric material containing Ag (silver) and Nb (niobium).

7. The piezoelectric material of claim 1, wherein in the main constituent at least 25.6 (atomic %), 30.25 (atomic %), 34.9% (atomic %), 44.2 (atomic %), 53.5 (atomic %), 62.8 (atomic %), 72.1 (atomic %), 75.4 (atomic %), 81.4 (atomic %), 87.4 (atomic %), 90.7 (atomic %), 93.8 (atomic %), 95.35 (atomic %), 96.28 (atomic %), 96.9 (atomic %) are Al while the remaining balance is a combination of binary doped AlN piezoelectric material containing Ag (silver), Nb (niobium) and Sc (scandium).

8. The piezoelectric material of claim 1, wherein the piezoelectric material is part of a piezoelectric.

9. The piezoelectric material of claim 8, wherein the piezoelectric device selected from:
an electro acoustic resonator, a SAW resonator, a SAW filter, a solidly mounted reflector,
SMR, BAW resonator, a (SMR-)BAW filter, a guided BAW(GBAW) resonator, a GBAW filter, a film bulk acoustic wave (FBAR) resonator, a FBAR filter,
a device working with Lamb waves, acoustic plate wave (APW), Rayleigh SAW (R-SAW), Sezawa mode waves, shear-horizontal SAWs (SH-SAWs), Love mode waves, pseudo-surface acoustic waves (PSAW) or Leaky SAWs (LSAW),
a multiplexer, a duplexer, a quadplexer, a hexaplexer, a multiplexer based on any of the above types of resonators, a piezoelectric generator, a piezoelectric sensor, a mass sensor, a microfluidic sensor, a piezoelectric transducers, an energy harvester, an ultrasound device, a transducer or transmitter, a piezo (MEMS) microphone or a similar device that utilizes direct or reverse piezoelectric effect in a thin film or bulk ceramic form.
